(19) United States
(12) Patent Application Publication
(10) Pub. No.: US 2013/0069100 A1
(43) Pub. Date: Mar. 21, 2013

(54) REUSABLE HIGH POWER LED MODULE AND METHODS THEREOF

(71) Applicants: Redwan Ahmed, Long Island City, NY (US); Brian Bennett, New York, NY (US); Michael Handerhan, New York, NY (US)

(72) Inventors: Redwan Ahmed, Long Island City, NY (US); Brian Bennett, New York, NY (US); Michael Handerhan, New York, NY (US)

(21) Appl. No.: 13/470,917

(22) Filed: May 14, 2012

Related U.S. Application Data
(60) Provisional application No. 61/486,019, filed on May 13, 2011.

(51) Int. Cl. H01L 33/48

(52) U.S. Cl. 257/99; 29/402.08; 257/E33.057

(57) ABSTRACT

The present invention is directed to a reusable, single-source, high-power LED module utilizing a subset of components that may be quickly replaced in the field without tools when the useable life of an LED chip expires. The reusable LED module may be used with a variety of lamp assemblies to generate an even wider variety of light distributions. In particular, drive currents, color temperatures, LED bin codes, optical lenses, and lamp assemblies may be varied to achieve a desirable light distribution.

### PRIORITY STATEMENT

This application claims the benefit of U.S. Provisional Application No. 61/486,019, filed May 13, 2011.

### FIELD OF THE INVENTION

The present invention relates to colored and white light-emitting diode (LED) modules, among other things. In particular, the present invention relates to high-power LED modules that are substantially reusable and configured for tool-less field replacement of one or more components, such as an LED chip.

### BACKGROUND OF THE INVENTION

Conventional filament bulbs are becoming increasingly obsolete, at least within some lighting applications. Nowadays, the efficiency of filament bulbs is relatively low, in the order of about 15 lumens per Watt. High intensity discharge (HID) bulbs offer better efficiencies at roughly 75-80 lumens per Watt as a system. Yet these conventional light sources may operate at high temperatures, may have limited lifespan, and may require high starting voltages, which can in turn present safety concerns. Moreover, both of these conventional light sources emit light spherically, meaning light is distributed in all directions. Although this characteristic may be advantageous in some environments, it may be inefficient in other environments where a spherical light distribution is unnecessary or even undesirable.

Due to recent advancements in the field of semiconductor technology, lamps utilizing light-emitting diodes (LEDs) now offer advantages over conventional light sources. Such advantages include, for example, enhanced diversity of luminescent color, luminance, durability, and power consumption. Further, LEDs are being used in an increasing number of applications, such as in vehicle instrument panels, televisions, and mobile telephones. LEDs may also be used in outdoor applications, such as in traffic lights and external vehicle lights. LEDs intended for outdoor applications are often designed to emit Type IV and Type V lighting distribution patterns, even though outdoor LEDs may generate all types of lighting distribution patterns.

Type IV lighting distributions are used near a side of an area-to-be-lit because of their characteristic asymmetrical distributions with respect to a center of a light fixture. Such distributions provide even candlepower at the perimeter of an oval-like pattern on a surface-to-be-lit, and the oval-like pattern projected onto the surface-to-be-lit has a center that is offset from the light fixture. Moreover, the shape and skew of the oval-like pattern may be altered to achieve other types of distribution patterns. By contrast, Type V lighting typically casts a generally-circular distribution of candlepower onto a surface-to-be-lit, which is often a horizontal surface such as, for example, a parking lot or a roadway. Because the generally-circular distribution is essentially the same at all lateral angles around the luminary, a light causing a Type V distribution is usually placed near the center of an area-to-be-lit.

To generate sufficient luminosity, many LED-based lamps must use clusters of individual LEDs housed together as a single lamp module, which can be costly. Recently, the lighting industry has started using high-power, single-chip LED lamp modules, although such lamp modules have lagged in generating sufficient luminance. Moreover, single-chip LEDs require a relatively high amount of electricity and generate a significant amount of heat as a byproduct of operation. Dissipating this heat can present safety concerns. A still further drawback to single-chip LED lamp modules is the cost and inconvenience of replacing an entire lamp module each time a single-chip LED approaches the end of its useful life, as is typical in the field. In some instances, the useful life of an LED may be said to expire when the LED can only produce 70% of the lumens at which the LED is initially rated (L70). Yet another disadvantage is that most if not all existing LED modules require tooling for assembly and disassembly such that the LED chip may not be replaced in the field.

There is currently no apparatus, system, or method that teaches a reusable high power LED module that generates sufficient luminance and dissipates heat sufficiently. The present invention satisfies these and other needs.

### SUMMARY OF THE INVENTION

The present disclosure concerns a largely-reusable high power LED module that can be utilized as a light source in a variety of types of light fixtures. The LED module may be used, for example and without limitation, with LED area lights, LED Wallpacks, LED Highbay lights, and the like. Even though the LED module can be replaced quickly in the field, the LED module is capable of routinely generating over 6,000 lumens of light.

In general, the LED module may include a platform, a semiconductor LED chip, a first collar, and a second collar. More specifically, the platfotin may have an open end and a closed end. The LED chip may be affixed to the closed end of the platform such that a light-emitting surface of the LED chip faces the open end of the platform. Further, the first collar may have a rim disposed near a top edge of the first collar and a first set of threads disposed near a bottom portion of the first collar. The rim may be provided for attaching the LED module to another object, surface, heat sink, or other location where the LED module will be stationed. The first set of threads may be engageable with a second set of threads on the second collar.

To assemble the LED module, the platform may be positioned within the first collar. Thereafter, the second collar may be secured to the first collar such that the platform is retained largely within the first collar. To secure the second collar to the first collar, the second set of threads of the second collar may be engaged with the first set of threads of the first collar. To supply electricity to the LED chip, a power cord may be provided that extends through both a hollow boss in the platform and a slot in the first collar.

In one embodiment, when the useful life of the LED chip of the LED module expires, one may simply unthread the second collar from the first collar to remove the platform with the attached LED chip. A new LED chip attached to a different platform may be inserted into the first collar and retained by threading the second collar onto the first collar. Reusing the collars and any attached lamp fixture cuts down on replacement costs. By leaving the first collar attached to the location where the light is stationed and by merely having to unthread the first and second collars to replace the LED chip, one may replace the LED chip in the field without needing tools.

In some embodiments, it may be advantageous to use the LED module in lamp fixtures that are designed to distribute the light emitted from the LED module in certain patterns. Once the inner collar of the LED module is affixed to such lamp fixtures, the LED chip and the platform may likewise be replaced without tools in the field. Besides using different lamp fixtures, the distribution of light from the LED module may be further controlled by varying optical lenses, drive currents, color temperatures, LED bin codes, and the like.

These and other aspects, features, and advantages of the present invention will become more readily apparent from the attached drawings and the detailed description of the preferred embodiments, which follow.

### BRIEF DESCRIPTION OF THE DRAWINGS

The preferred embodiments of the invention will be described in conjunction with the appended drawings provided to illustrate and not to the limit the invention, where like designations denote like elements, and in which:

FIGS. 1A-1C are perspective, side, and bottom views, respectively, of one embodiment of a high-power light-emitting diode (LED) module.

FIGS. 2A-2B illustrate a sub-set of components of the LED module of FIGS. 1A-1C that may be quickly replaced in the field when the useful life of an attached LED chip expires.

FIGS. 3A-3B are perspective and cross-sectional views, respectively, of an inner collar of an LED module.

FIGS. 4A-4C are multiple perspective views and a cross-sectional view, respectively, of a platform used in an LED module.

FIG. 5 is an isometric view showing an LED chip that may be utilized in some embodiments of an LED module.

FIGS. 6A-6D are two perspective views, a side view, and a cross-sectional view of an outer collar that may be used in some embodiments of an LED module.

FIGS. 7A-7B are exploded views showing several embodiments of an LED module.

FIG. 8 provides a section view of one embodiment of an LED module, though several components have been omitted to provide perspective.

FIG. 9 is a bottom view of an LED module showing an LED chip and attached power cord as routed through several components of the LED module.

FIGS. 10A-10D are perspective views of an area light that may utilize an LED module; FIG. 10E is a cross-sectional view of the area light that may utilize the LED module.

FIGS. 11A-11C are perspective, side, and bottom views, respectively, of a lamp fixture that may utilize an LED module.

FIG. 12 provides two perspective views of a highly-reflective optical module that may be used to focus light from an LED chip.

FIG. 13 shows a side view of one embodiment of an LED module utilizing a highly-reflective optical module for focusing light from an LED chip.

FIGS. 14A-D show electrical testing results of an embodiment of an LED module.

### DETAILED DESCRIPTION

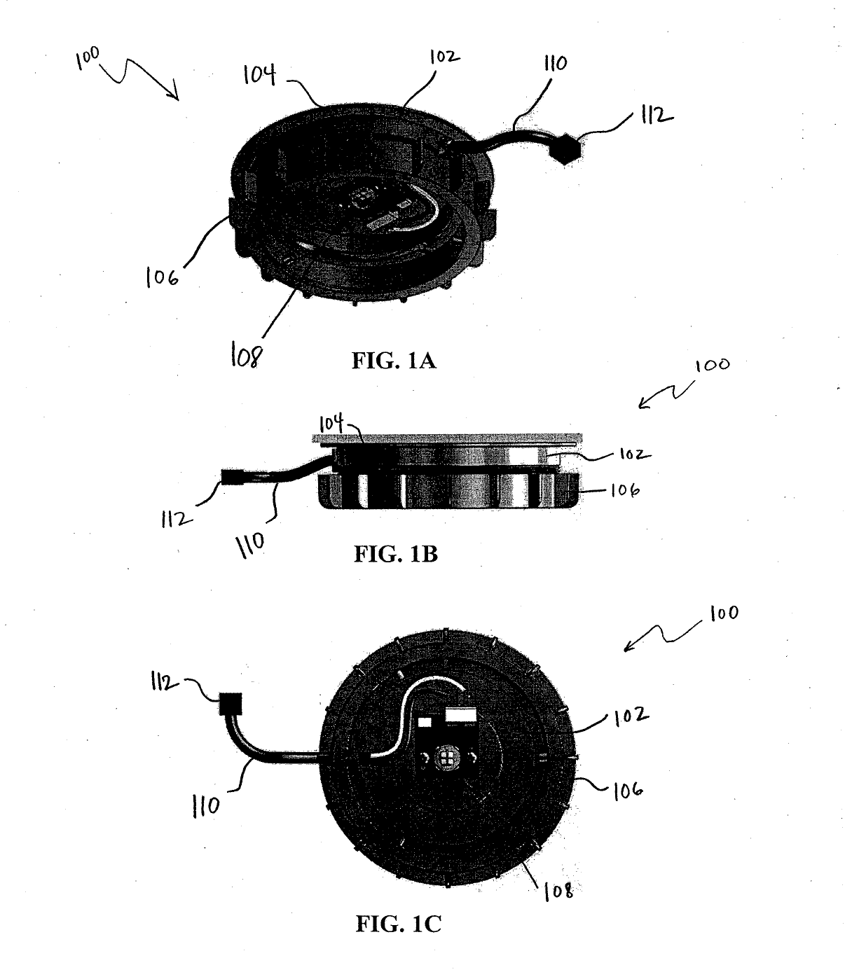

FIGS. 1A-1C show perspective, side, and bottom views, respectively, of one embodiment of a high-power, single-source light-emitting diode (LED) module 100 that may be used with a multitude of lamp assemblies. As will be described below, the LED module 100 is energy-efficient and may be used to light a variety of indoor and outdoor environments. In general, the LED module 100 may include a platform 102, an inner collar 104, an outer collar 106, an LED chip 108 supported along the platform 102, and a cord 110 with a power plug 112 for delivering power to the LED chip 108. While combinations of LEDs may be employed, it should be noted that in the preferred embodiment, the LED module 100 uses only one LED chip 108.

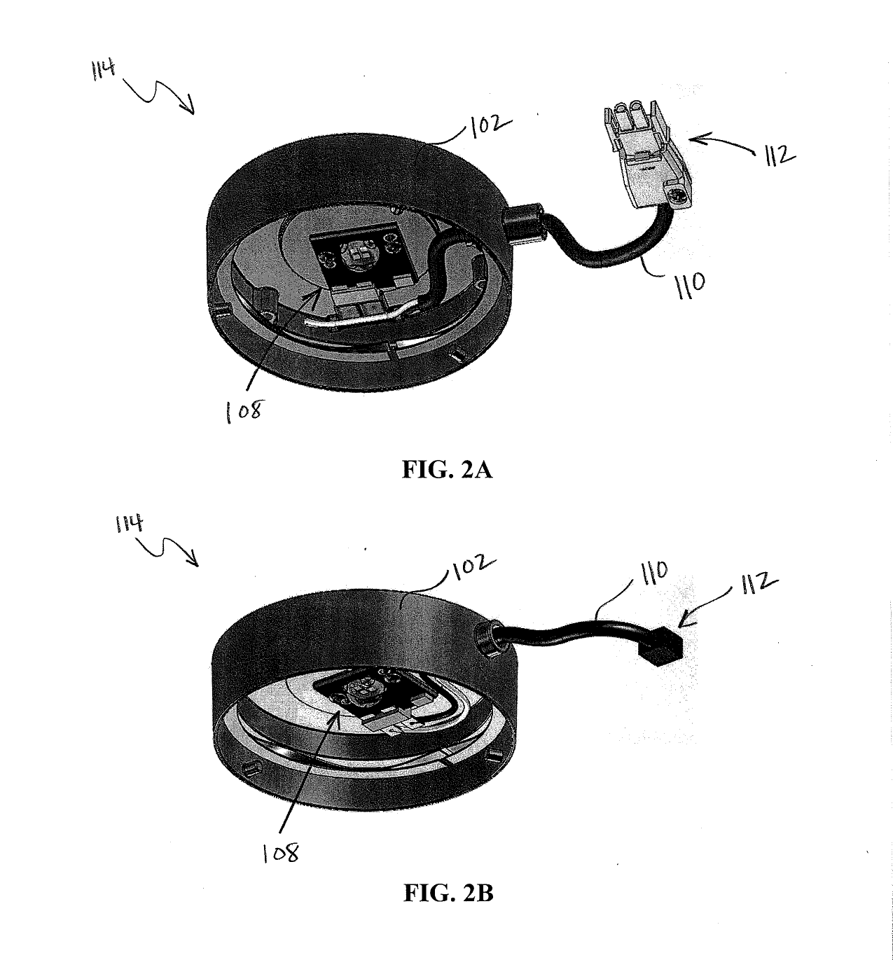

Replacing an entire LED module, as is typical in the lighting industry, is not only costly, but wasteful too. FIGS. 2A-2B, which differ only in that each has a different type of power plug 112, show several components of the LED module 100 that may be easily disassembled from the LED module 100 and replaced in the field when the LED chip 108 reaches the end of its useful life (e.g., L70). As opposed to replacing the entire LED module 100, one may instead disassemble the LED module 100 by hand and merely replace several components of the LED module 100. Collectively, the replaceable components may be referred to as a unit 114.

In other embodiments, the present disclosure contemplates that just the LED chip 108, the cord 110, and the power plug 112 may be replaced. In those embodiments, the platform 102 may be reused along with the rest of the LED module 100.

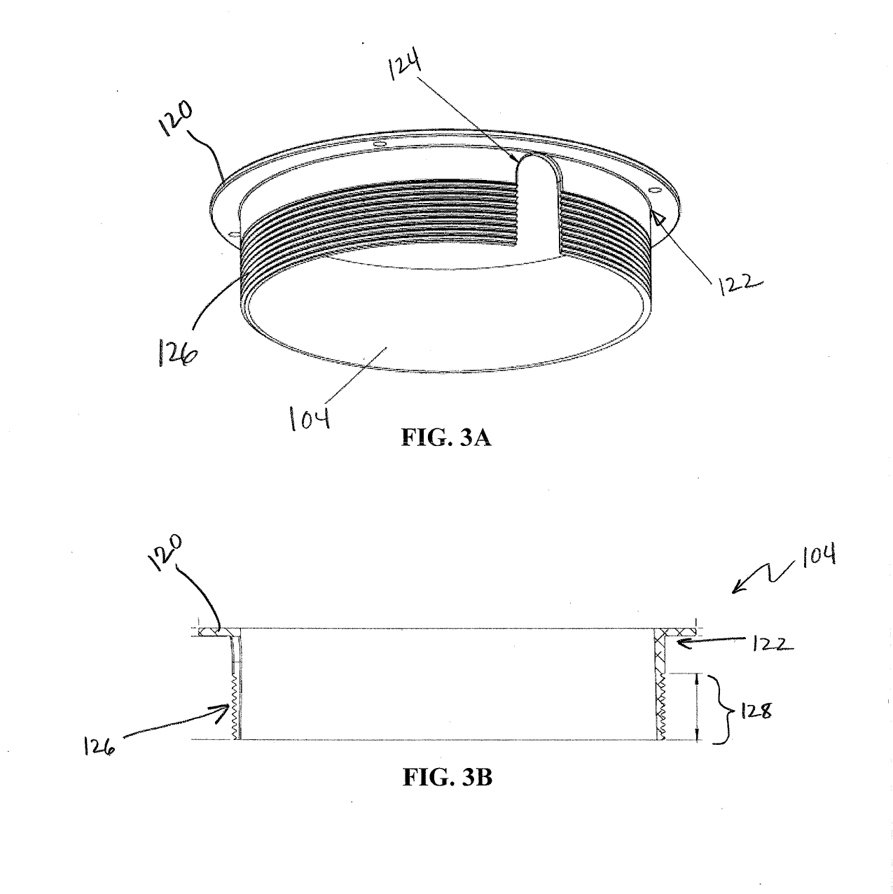

With reference to FIGS. 3A-3B, the inner collar 104 is shown in a perspective view and a cross-sectional view, respectively. The inner collar 104 may have a rim 120 that extends generally outward from a top portion 122 of the inner collar 104. The rim 120 may be advantageous for attaching the LED module 100 to a surface, object, or heat sink where the LED module 100 will be stationed. The inner collar 104 may also have an open-ended slot 124 for receiving other components of the LED module 100, as described below. Moreover, the inner collar 104 may have external threads 126 disposed along a bottom portion 128 of the inner collar 104 for mating with internal threads disposed within the platform 102.

In a preferred embodiment, the inner collar 104 may be generally circular with an internal diameter of about 123-125 millimeters. The external diameter of the inner collar 104, including the rim 120, may be 149 millimeters, while the thickness of the rim 120 may be just over 2 millimeters. The height of the inner collar 104 in the preferred embodiment may be about 34 millimeters. And further, the width of the open-ended slot 124 may be about 16 millimeters, with the open-ended slot 124 extending substantially up to the top portion 122 of the inner collar 104 where the rim 120 may be disposed. Also, the external threads 126 may be occupy approximately 20 millimeters near the bottom portion 128 of the inner collar 104. As with several of the other components of the LED module 100, the platform may be formed of die-cast aluminum and have a natural anodized satin finish.

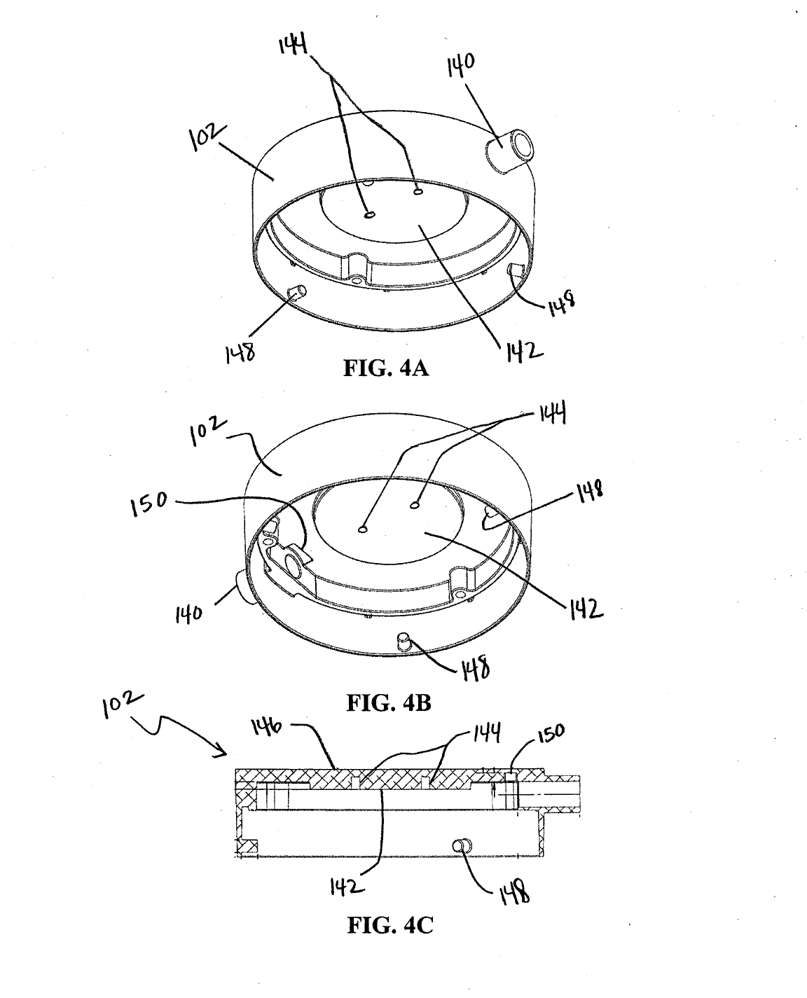

The platform 102 of the LED module 100 is shown in a perspective view in FIG. 4A, in a different perspective view in FIG. 4B, and in a cross-sectional view in FIG. 4C. The platform 102 may include a hollow boss 140 through which the cord 110 may be configured. In one embodiment, the platform 102 may be sized for placement just within the inner collar 104. Similarly, the hollow boss 140 may be sized for placement just within the open-ended slot 124 of the inner collar 104. The platform 102 may also include a surface 142 to which the LED chip 108 may be attached. In particular, the surface 142 may contain a plurality of mounting holes 144 for receiving fasteners that attach the LED chip 108 to the platform 102. A top surface 146 that opposes the surface 142 for receiving the LED chip 108 may be machined flat such that it is free of imperfections. Having the top surface 146 machined flat may help facilitate optimal heat transfer away from the LED chip 108 when operational. Further, the platform 102 may include a plurality of twist-lock studs 148 for aiding assembly of the LED module 100, as described below. Even further, the platform 102 may include a recessed area 150 for receiving a rubber bushing that surrounds a portion of the cord 110 in some embodiments.

In a preferred embodiment, the platform 102 may be formed from die-cast aluminum and have a natural anodized satin finish. Also, the platform may be about 35 millimeters high and 121-122 millimeters in external diameter. The hollow boss 140 may be about 15 millimeters in external diameter and about 11 millimeters in internal diameter, with the hollow boss 140 being offset just a few millimeters below the top surface 146 of the platform 102. Additionally, the thickness of material between the surface 142 for receiving the LED chip 108 and the top surface 146 may be about 8 millimeters.

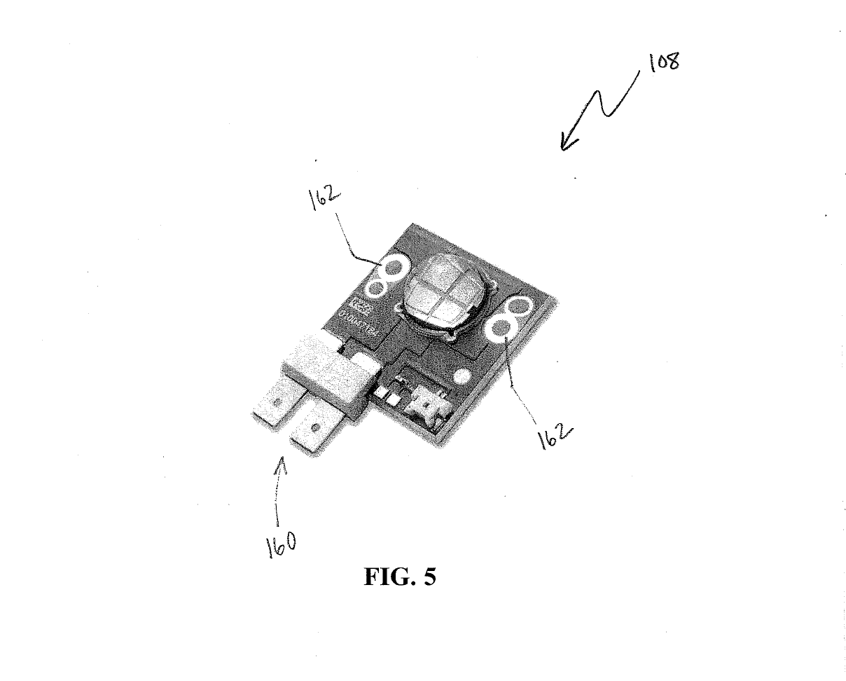

One skilled in the art will recognize that many types and brands of LED chips may be used with the LED module 100. FIG. 5 shows one exemplary LED chip 108 that may be used in some embodiments of the single-source LED module 100 and the replaceable unit 114. Specifically, the LED chip 108 may be a Luminous CSM-360 PhlatLight® LED package. Such LEDs offer a lifetime exceeding 50,000 hours at 70% lumen maintenance. The LED chip 108 may include electrical power leads 160, and the LED chip 108 may also include points of attachment 162 for securing the LED chip 108 to the platform 102. In general, the LED chip 108 is capable of producing 1,000-10,000 lumens depending on drive current, color temperature, and LED bin codes used.

A photometric testing report of the LED module 100 with the PhlatLight® LED package is shown below:

### Testing Instruments and Conditions:

Integrating sphere: Labsphere LMS-760
AC power supply: Extech 6610

### Ambient Temperature: 25°±1°

Drive condition: 6A
Testing time: 2 seconds

### Testing Result:

| | Voltage_{—} | | | | | | | |
|---|---|---|---|---|---|---|---|---|
| | Forward_{—} | PeakLum | | Bin | | | | |
| LED_S/N | Volts | _Lumens | Lm/W | Title | CIE_x | CIE_y | CCT | CRI |
| 061025801 | 13.90 | 6152.8 | 73.8 | N3 | 0.3600 | 0.3567 | 4486 | 64.4 |
| 061025809 | 13.85 | 6179.2 | 74.4 | P3 | 0.3622 | 0.3616 | 4442 | 64.7 |
| 061025831 | 13.93 | 5808.4 | 69.5 | N3 | 0.3572 | 0.3532 | 4560 | 65.2 |
| 061024057 | 13.92 | 6122.0 | 73.3 | N3 | 0.3584 | 0.3548 | 4527 | 65.0 |

The testing report shows that the LED module 100 is capable of routinely generating over 6,000 lumens.

Electrical testing reports of the LED module 100 with the PhlatLight® LED package is shown below as TEST Driver 1-4 and in FIGS. 14A-D, respectively.

### Testing Instruments and Conditions:

Chroma AC source 61503

### Chroma Power Meter 66202

### Oscilloscope: LeCroy LT354

### Current Probe LeCroy AP015

### Voltage Probe LeCroy SI-800P

Testing time: 30 seconds

### Testing Result:

TEST Driver. 1 S/N: RB12138195 for LED NO. 1 (061025801)

| V_{ac} input | 120 V/60 Hz | 230 V/50 Hz | 277 V/50 Hz |
|---|---|---|---|
| Iin (A) | 0.808 | 0.432 | 0.368 |
| Power_in (W) | 96.1 | 94.9 | 94.6 |
| Power Factor | 0.991 | 0.953 | 0.925 |
| Efficiency(%) | 87.5 | 88.3 | 88.5 |
| LED-Vout (Vᵣₘₛ) | 13.884 | 13.848 | 13.814 |
| LED-Iout (Aᵣₘₛ) | 6.055 | 6.054 | 6.062 |
| Power LED (W) | 84.1 | 83.8 | 83.7 |

TEST Driver. 2 S/N: RB12138196 for LED NO. 2 (061025809)

| V_{ac} input | 120 V/60 Hz | 230 V/50 Hz | 277 V/50 Hz |
|---|---|---|---|
| Iin (A) | 0.8016 | 0.4281 | 0.366 |
| Power_in (W) | 95.3 | 94.0 | 94.1 |
| Power Factor | 0.991 | 0.954 | 0.9253 |
| Efficiency (%) | 87.4 | 88.3 | 88.3 |
| LED-Vout (Vᵣₘₛ) | 13.698 | 13.644 | 13.658 |
| LED-Iout (Aᵣₘₛ) | 6.084 | 6.084 | 6.083 |
| Power LED (W) | 83.3 | 83.0 | 83.1 |

TEST Driver. 3 S/N: RB12138197 for LED NO. 3 (061025831)

| V_{ac} input | 120 V/60 Hz | 230 V/50 Hz | 277 V/50 Hz |
|---|---|---|---|
| Iin (A) | 0.796 | 0.427 | 0.365 |
| Power_in (W) | 94.6 | 93.6 | 93.7 |
| Power Factor | 0.991 | 0.952 | 0.923 |
| Efficiency (%) | 87.6 | 88.6 | 88.5 |
| LED-Vout (Vᵣₘₛ) | 13.738 | 13.733 | 13.728 |
| LED-Iout (Aᵣₘₛ) | 6.038 | 6.039 | 6.04 |
| Power LED (W) | 82.9 | 82.9 | 82.9 |

TEST Driver. 4 S/N: RB12082688 for LED NO. 4 (061024057)

| V_{ac} input | 120 V/60 Hz | 230 V/50 Hz | 277 V/50 Hz |
|---|---|---|---|
| Iin (A) | 0.798 | 0.429 | 0.366 |
| Power_in (W) | 94.9 | 94.2 | 94.1 |
| Power Factor | 0.991 | 0.954 | 0.925 |
| Efficiency (%) | 87.1 | 88.2 | 88 |
| LED-Vout (Vᵣₘₛ) | 13.711 | 13.758 | 13.724 |
| LED-Iout (Aᵣₘₛ) | 6.032 | 6.037 | 6.037 |
| Power LED (W) | 82.7 | 83.1 | 82.8 |

An embodiment of the LED module 100 made in accordance with the present disclosure utilizes a cross-platform design for use in interior or exterior fixtures requiring high lumen output, high efficiency and long life. A single LED, such as the single Big Chip™ LED, can power the LED module 100 to eliminate multi-source shadowing, and provide ultra-bright output with fewer failure points and higher reliability. Further, as described herein, the LED module 100 is designed for easy replacement in the field without tools, and is ideal for high bay, security and/or area lighting applications. Some of the features and benefits of this embodiment includes, but are not limited to, the production of up to 6,500 lumens, with a performance of a 175 W HID lamp. The field replaceable module and power supply can generate over 100 lumens per watt at 3.15 A. The LED module 100 works with a variety of optics and has a quick connect module power plug, durable aluminum housing with a locking ring, and a 50,000 plus hour LED lifetime. The preferred embodiment also uses built-in die-cast aluminum heat sinks. There are numerous applications for this embodiment, including, but not limited to, working with a wide variety of reference designs, such as outdoor areas, parking lots, canopies, high bay, wall pack, pendant, and high-output decorative pendant lights.

The product performance for this embodiment is shown below:

| | | Color | | |
|---|---|---|---|---|
| Product | Input Current | Temperature | Lumens | Efficiency (3A) |
| SoloLux | 3.0 A to 6.0 A | 6500 K | 3,000-6,500 | 100 + LPW |
| Module | | 5700 K | 3,000-6,500 | 100 + LPW |
| | | 4500 K | 2,700-6,000 | 90 + LPW |

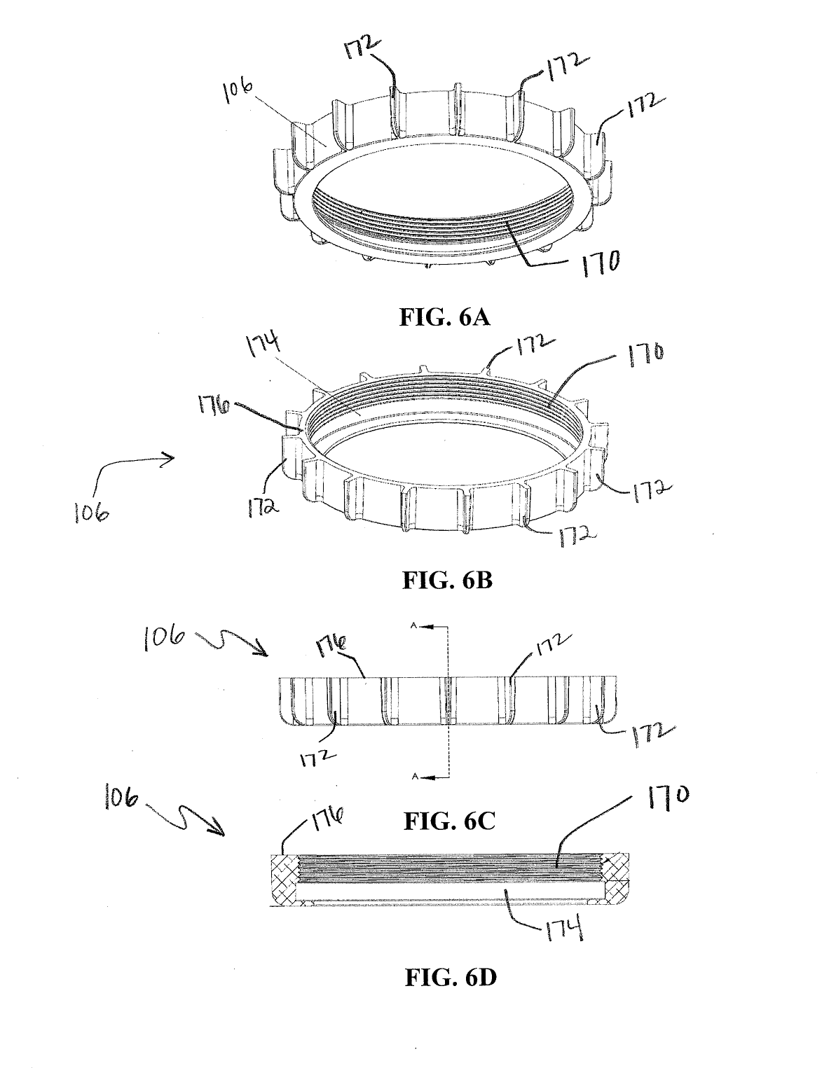

Referring now to FIGS. 6A-6D, one embodiment of the outer collar 106 is shown in a perspective view in FIG. 6A, in another perspective view in FIG. 6B, in a side view in FIG. 6C, and in a cross-sectional view A-A in FIG. 6D. To help secure the LED module 100, the outer collar 106 may include internal threads 170 that mate with the external threads 126 of the internal collar 104. To enable one to twist the outer collar 106 onto the internal collar 104, the outer collar 106 may also include a plurality of ribs 172 that provide an effective contact surface for applying torque to the outer collar 106 during assembly and disassembly. The outer collar 106 may further include an internal recessed area 174 for housing a washer (not shown) once assembled.

In a preferred embodiment, the outer collar 106 may be about 22 millimeters high and have an external diameter of about 152 millimeters. The outer collar 106 may also be formed from die-cast aluminum and have a natural anodized satin finish. Additionally, the internal threads 170 may extend about 12 millimeters downward from a top 176 of the outer collar 106. In general, the internal diameter of the outer collar 106 may be about 132 millimeters.

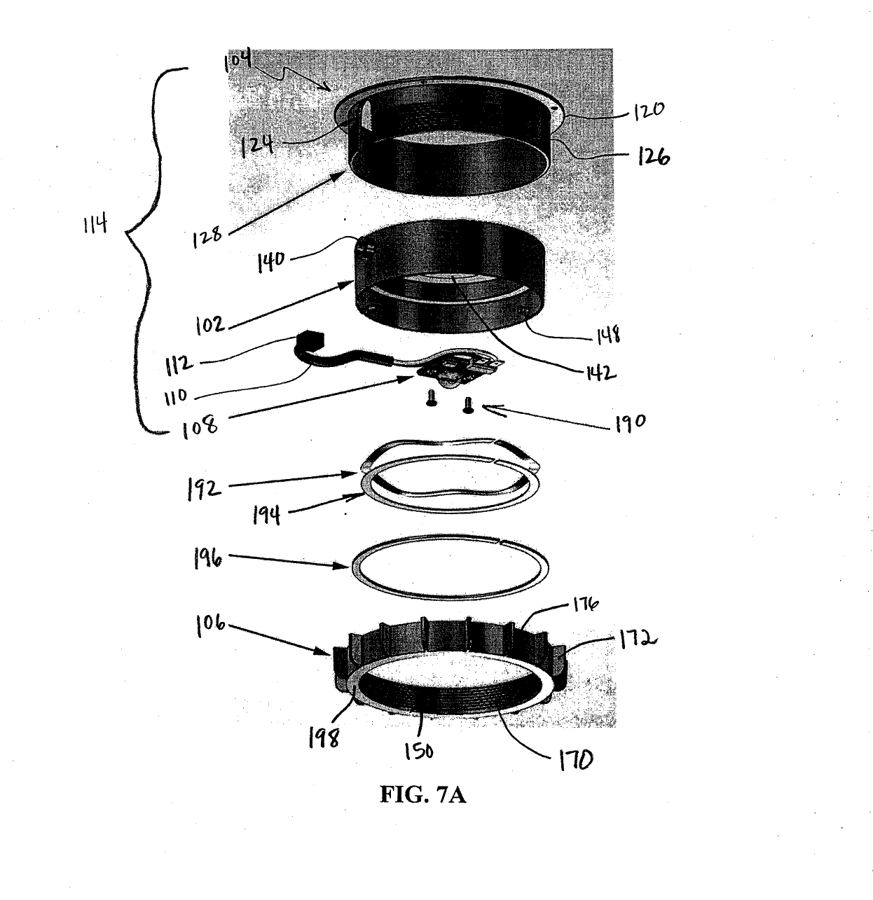

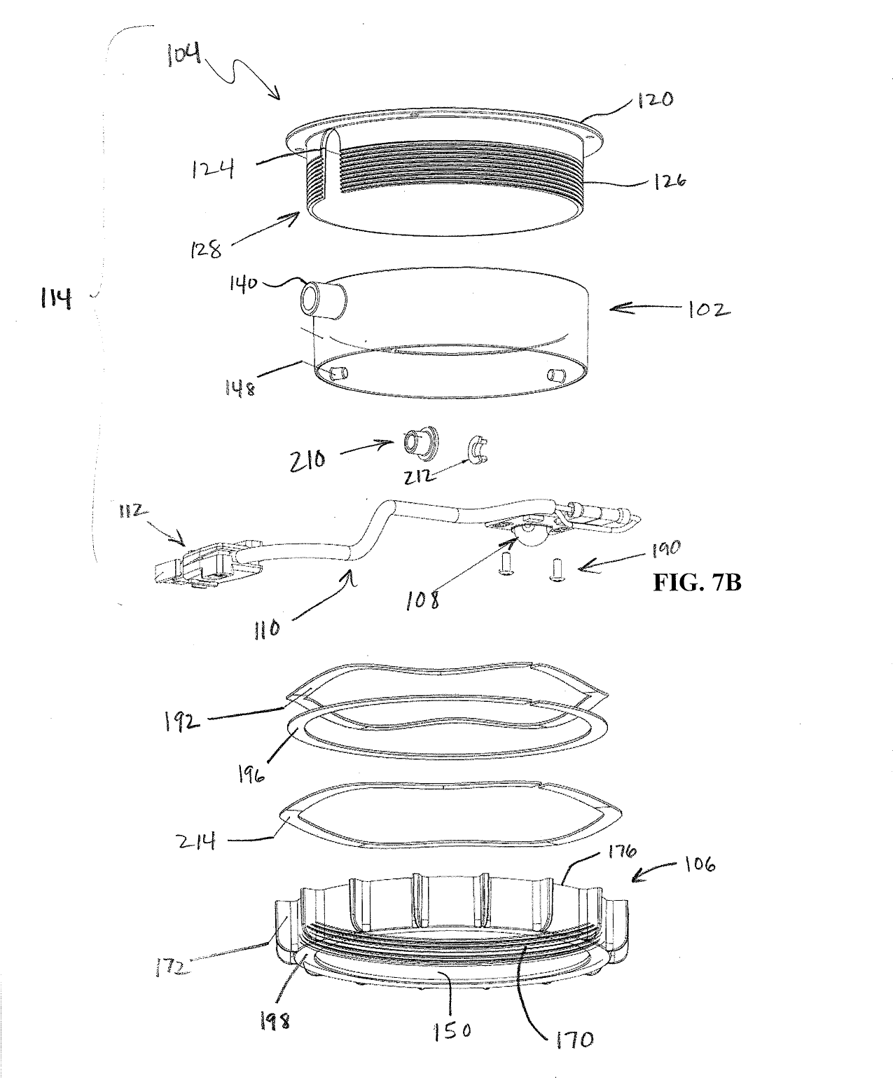

FIGS. 7A-7B show exploded views of several embodiments of the LED module 100 that may easily be disassembled and reassembled when the LED chip 108 reaches the end of its useful life (e.g., L70). In particular, FIG. 7A shows the LED chip 108, which may be secured to the surface 142 in the platform 102 with one or more fasteners 190. Thermal contact grease may be used between the LED chip 108 and the surface 142 to facilitate heat transfer. Once the LED chip 108 is secured to the surface 142 in the platform 102 with the fasteners 190, the cord 110 may be routed through hollow boss 140 of the platform 102. The power plug 112, which can incorporate a quick-connect type power plug, may then be electrically coupled to the cord 110. Thus far, assembly of the replaceable unit 114 shown in FIG. 2B has been described.

To assemble the LED module 100, the replaceable unit 114 may next be slid into the inner collar 104. Specifically, the hollow boss 140 with the cord 110 and power plug 112 protruding may slide into the open-ended slot 124 of the inner collar 104. Once positioned, the hollow boss 140 may slide up to or almost up to the rim 120 of the inner collar 104.

Before retaining the replaceable unit 114 within the inner collar 104 via the outer collar 106, a washer 192 and a shim 194 may be located within the platform 102 and above the twist-lock studs 148. The washer 192 and the shim 194 may be helpful when securing an attachment of a larger lamp fixture to the LED module 100. The washer 192 and the shim 194 may help distribute load, may provide a level surface, or may provide a better fit, for example. In one embodiment, the washer 192 may be a rotor clip wave washer, which may act as a spring between the shim 194 and the inner collar 104. Further, a second shim 196 may be positioned within the recessed area 150 of the outer collar 104. The second shim 196, which may sit between a lower rim 198 of the outer collar 106 and the bottom portion 128 of the inner collar 104, may serve several purposes. For example, the second shim 196 may help distribute any load between the lower rim 198 and the bottom portion 128. The second shim 196 may also serve as a wear pad, a spacer, a locking device, or a vibration-dampening device between the lower rim 198 and the bottom portion 128 of the inner collar 104.

Once the washer 192 and shims 194, 196 are in place, the outer collar 106 may be threaded onto the inner collar 104. That is, the internal threads 170 of the outer collar 106 may engage with the external threads 126 of the inner collar 104. A person assembling the LED module 100 may use the ribs 172 of the outer collar 106 and the twist-lock studs 148 of the inner collar 104 to torque the outer collar 106 onto the inner collar 104. As the outer collar 106 is threaded onto the inner collar 104, the top 176 of the outer collar 106 may force the hollow boss 140 up into the open-ended slot 124 of the inner collar 104. The hollow boss 140 may be rigid such that one does not have to worry about compressing or kinking electrical wires within the cord 110 as the top 176 of the outer collar 106 forces the replaceable unit 114 up into the inner collar 104. As the outer collar 106 is secured around the inner collar 104, the lower rim 198 of the outer collar 106 and the bottom portion 128 of the inner collar 104 may come into contact with the second shim 196 disposed within the recessed area 150 of the outer collar 106.

FIG. 7B shows an embodiment that is similar to that shown in FIG. 7A. In FIG. 7B, however, the cord 110 that is shown to be attached to the LED chip 108 is different than the cord 110 in FIG. 7A. The power plug 112 in FIG. 7B is also different. The embodiment of the LED module 100 shown in FIG. 7B also includes a rubber bushing 210 and a metal strain relief bushing 212, which are not present in FIG. 7A. The rubber bushing 210 may be inserted within the hollow boss 140 of the platform 102. In some embodiments, a portion of the rubber bushing 210 may occupy the recessed area 150 shown in FIGS. 4B-4C. The rubber bushing 210 may provide an interface between the cord 110 and the hollow boss 140 that helps dampen vibrations between these components and others that are in communication therewith. The metal strain relief bushing 212 may also be oriented around the cord 110 and adjacent to the rubber bushing 210. The metal strain relief bushing 212 may enhance the dampening effects of the rubber bushing 210.

Still another difference is that a second washer 214 may be used instead of the second shim 196. In applications where the LED module 100 may experience a considerable amount of vibration, a washer—and in particular a wave washer—may be particularly helpful in dampening vibrations between the bottom portion 128 of the inner collar 104 and the lower rim 198 of the outer collar 106.

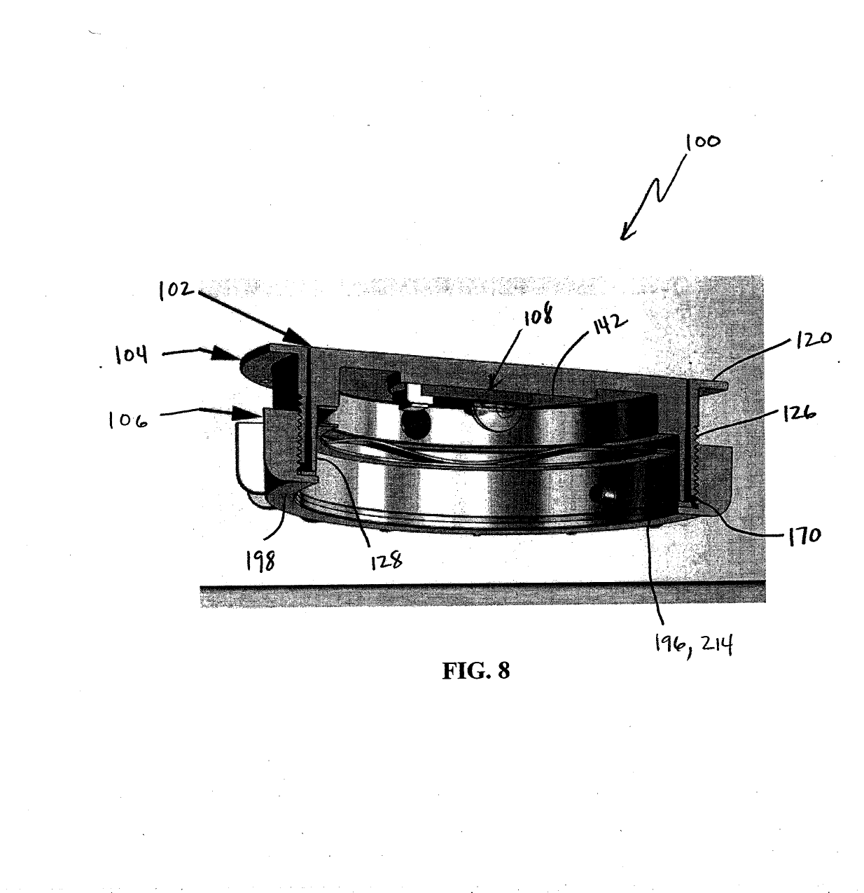

A section view of an assembled LED module 100 is shown in FIG. 8, although the cord 110 and power plug 112 have been omitted to provide perspective. As shown, the platform 102 is secured within the inner collar 104 by the engagement of the internal threads 170 on the outer collar 106 and the external threads 126 on the inner collar 104. The outer collar 106 may be secured onto the inner collar 104 to a point such that the top surface 146 sits flush with the rim 120 of the inner collar 104. As so, the top surface 146 and the rim 120 may mate with a surface (not shown) of an object to which the LED module 100 is secured. Also, the bottom portion 128 of the inner collar 104 and the lower rim 198 of the outer collar 106 are shown to be in contact with and separated by either the second washer 214 or the second shim 196. The washer 192 and shim 194 have been located within the inner collar 104 and above the twist-lock studs 148, and the LED chip 108 has been secured to the surface 142 of the inner collar 104.

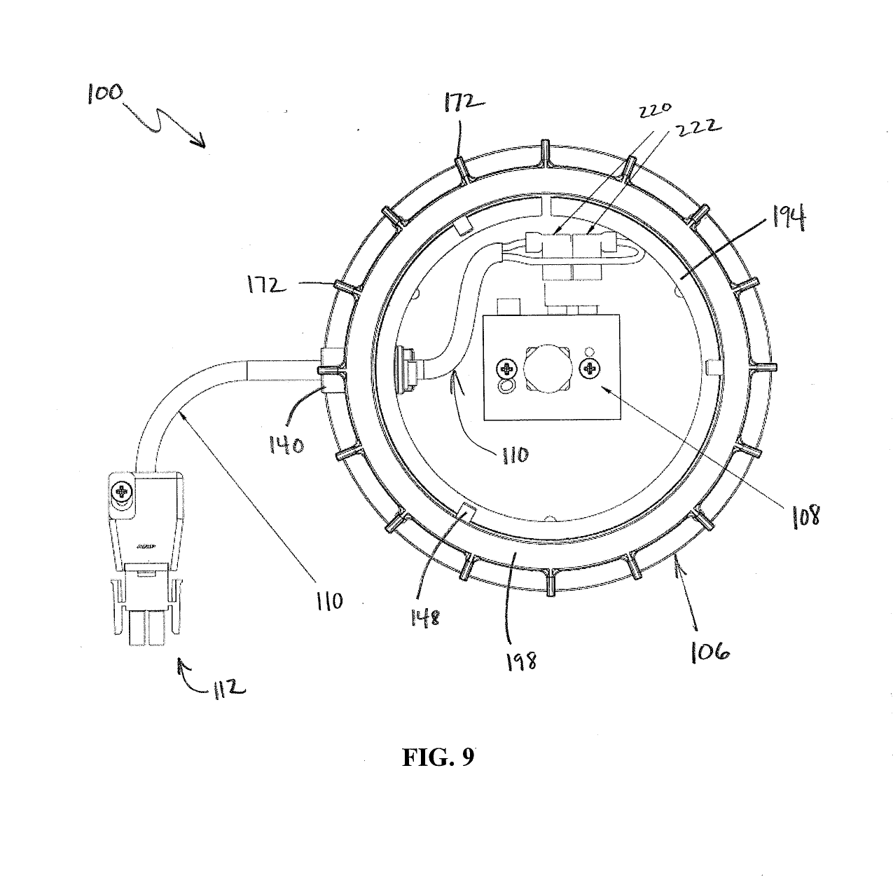

FIG. 9 shows a bottom view of an assembled LED module 100, with the cord 110 and power plug 112 attached. The cord 110 may be routed within the platform 102 to avoid obstructing light emitted from the LED chip 108. And as one skilled in the art will recognize, it may be advantageous to use high temperature wiring materials when constructing the cord 110 and its constituents, particularly because LED chips are known to give off a considerable amount of heat. Moreover, two insulating connectors 220, 222 are shown for connecting the cord 110 to the LED chip 108. In one embodiment, the insulating connectors 220, 222 may be two female right-angle nylon insulating connectors available through the Panduit Electrical Group.

As can be understood from the aforementioned description and corresponding figures, the procedure for replacing the unit 114 when the LED chip 108 reaches its useable life is rather simple. Namely, the outer collar 106 may be unscrewed from the inner collar 104, and the unit 114 may be removed from within the inner collar 104. The inner collar 104 may remain affixed to some other base object, surface, heat sink, or lamp module as a new unit 114 is positioned within the inner collar 104 and retained by the same outer collar 106. Perhaps more importantly, the LED module 100 is energy efficient, with the capability of producing over 100 lumens per Watt at a 3.15 amp (A) drive current. The LED module 100, even with only one LED light source, can also generate high output, that is, up to 6,500 lumens at a correlated color temperature of 6,500 Kelvin (K).

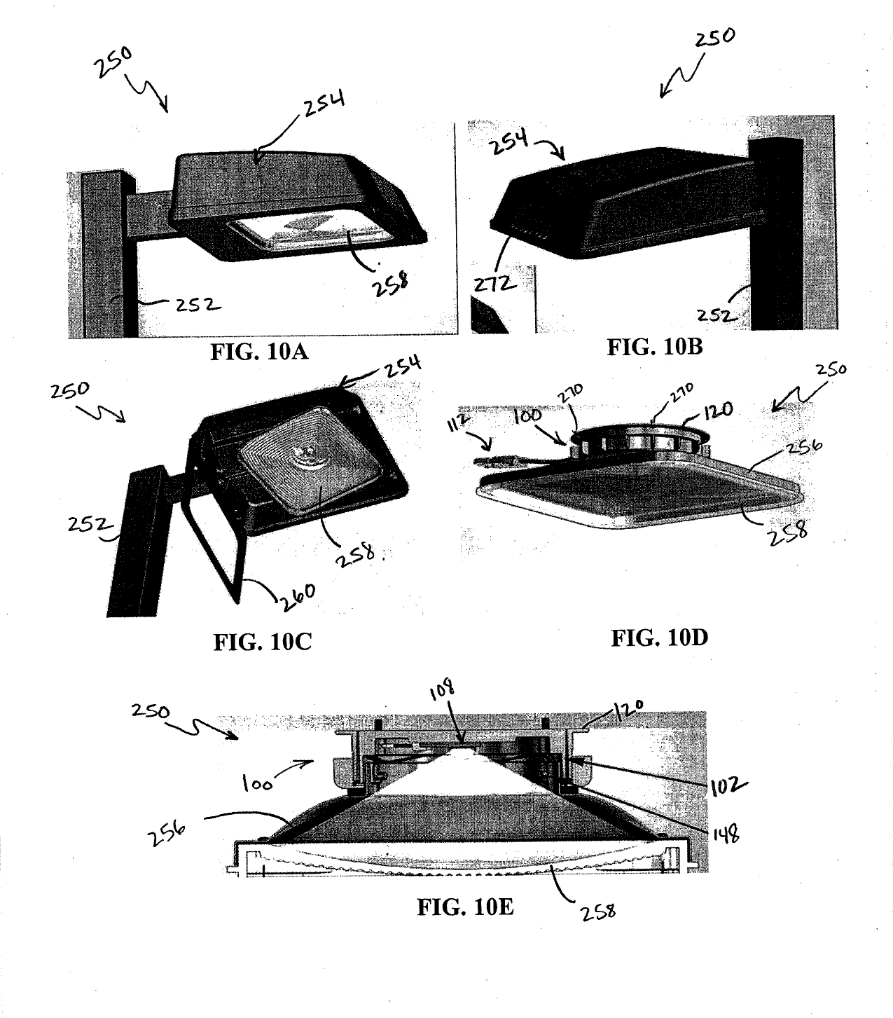

While the LED module 100 has been described in some detail, the LED module 100 may in some embodiments be used as a constituent of lamp modules that emit light in particular distributions. FIGS. 10-13 show several embodiments of lamp modules with which the LED module 100 may be used.

FIGS. 10A-10E show multiple views of a high-output LED area light 250 that can utilize the LED module 100. Altering the distribution of light from modules utilizing an array of LEDs is not effective, if not entirely unfeasible. But since the preferred embodiment of the LED module 100 utilizes a single LED, the distribution of light may be controlled by using different optical lenses. Although the present disclosure contemplates the use of the area light 250 for all types of lighting distributions, the area light 250 may be ideal for Type IV and Type V lighting distributions. Type IV lighting distributions are typically used near the sides of areas-to-be-lit because of their characteristic asymmetrical distributions with respect to a center of a light fixture. The area light 250 may produce a Type IV lighting distribution such that it generates even candlepower at the perimeter of an oval-like pattern on a surface-to-be-lit. The shape and skew of this oval-like pattern may be altered by adjusting the optical lens used with the area light 250. Further, Type V lighting typically casts a generally-circular distribution of candlepower that is essentially the same at all lateral angles around the luminary. Because the area light 250 may also emit a Type V distribution, the area light 250 may in some embodiments be placed near the center of an area-to-be-lit such as, for example, a parking lot or a roadway.

In any event, the area light 250 may generally include a support member 252, a housing 254, a lamp hood 256, a lens 258, and an entry door 260. The support member 252 may uphold the housing 254, which may in turn contain the LED module 100, the lamp hood 256, and the lens 258. In some embodiments, the support member 252 and the housing 254 may be formed from die-cast aluminum. The housing 254 may be accessible via the entry door 260, which may be hingedly attached to the housing 254. In one embodiment, opening and closing the entry door 260 may not require any tools. Magnets, for example, may be disposed along the housing 254 and the entry door 260 such that one may open the entry door 260 merely be applying a counteracting force.

As shown in FIG. 10C, the housing 254 may receive the LED module 100, the lamp hood 256, and the lens 258, which are shown separately in FIG. 10D. To illustrate, the rim 120 of the inner collar 104 may attach to the housing 254 via fasteners 270 that extend through the rim 120, or via any other fastening means. Although not shown, the lamp hood 256 may be secured to the LED module 100 in a number of ways including, for example and without limitation, a separate set of threads, “J” shaped slots that mate with the twist-lock studs 148 within the platform 102, or a weather-proof gasket. The weather-proof gasket may be particularly advantageous where the area light 250 is used with outdoor applications.

Yet another feature of the area lamp 250 is thermal radiation fins 272 acting as a heat sink, which may be disposed along the housing 254. The thermal radiation fins 272 help dissipate heat from the LED chip 108 packaged within the housing 254. Since the thermal radiation fins 272 are proximal to the LED chip 108 once the area lamp 250 is assembled, the fins both increase the surface area through which heat may radiate away from the area lamp 250 and provide channels through which heat may be carried away from the LED chip 108.

In addition, the lens 258 may attach to the lamp hood 256 with, for example, a clip feature, fasteners, or the like such that the lens 258 is easily replaceable in the field. In a preferred embodiment, the lens 258 is attached to the lamp hood 256 such that the lens 258 may be removed by hand, without any tooling. The lens 258 may in one embodiment be a precision-molded optical acrylic lens. Such a lens accurately controls lighting distribution and limits glare. What is more, the lamp hood 256 may accept a variety of optical lenses. This capability allows the LED module 100 and the area lamp 250 to be used for variety of lighting platforms. One skilled in the art will recognize that changing the drive current and/or the optical lens may help achieve a variety of lighting distributions and lumen outputs.

It is contemplated that in some embodiments, all of the components shown in FIG. 10D will be replaceable. In other embodiments, though, only the unit 114 shown in FIGS. 2A-2B is considered to be replaceable.

As can be seen in the cross-sectional view of FIG. 10E, the platform 102, the lamp hood 256, the lens 258, and any other pertinent components may be sized to prevent interference with the light distribution of the LED chip 108. Hence in one embodiment, the lens 258 may be roughly 229 millimeters across.

Though not shown, the area lamp 250 may be equipped with an LED driver that accepts inputs that range, at least in some embodiments, from 120 volts (V) through 277 V and 50 hertz (HZ) through 60 HZ. The area lamp 250 has proven to be greater than 90% efficient, produces a max luminous flux of 6,000-6,500 lumens at a 6.3 A drive current, has a color rendering index of greater than 70, and has a correlated color temperature of 4,500 K.

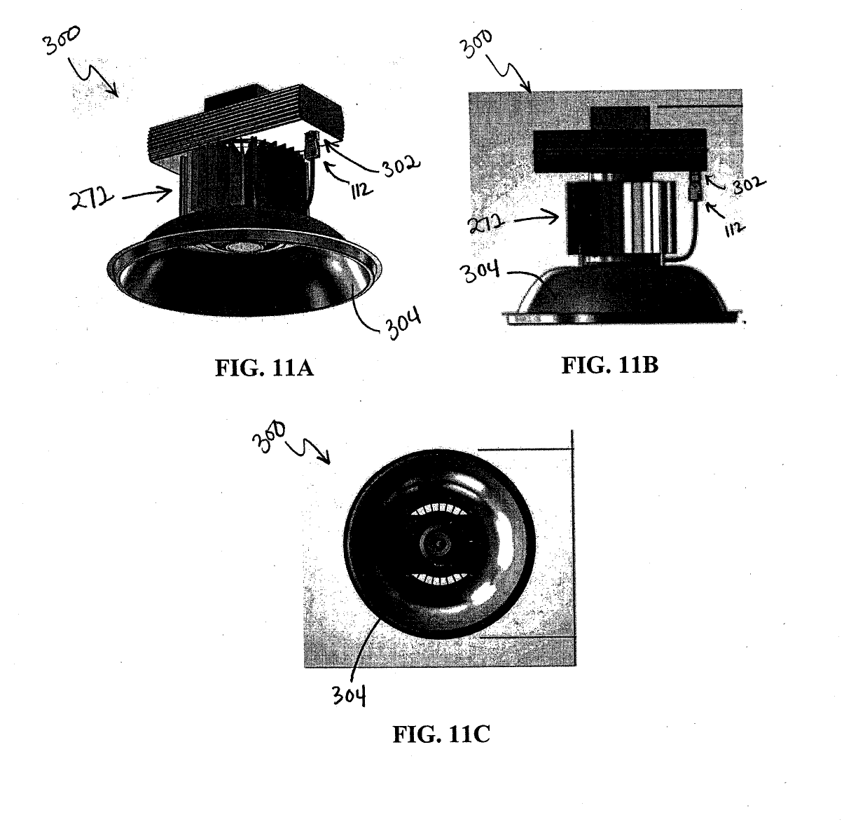

FIGS. 11A-13 show yet another embodiment that may utilize the LED module 100. FIGS. 11A-11C show perspective, side, and bottom views, respectively, of a high-output LED high bay lamp fixture 300. The lamp fixture 300 may have a power receptacle 302 to which the power plug 112 of the LED module 100 may connect. More specifically, the power receptacle 302 may include an LED driver that accepts inputs that range, at least in some embodiments, from 120 V through 277 V and 50 HZ through 60 HZ. The lamp fixture 300, like the area lamp 250, may emit light in a variety of distribution patterns because of the interchangeability of optical lenses and because of the single LED source.

Further like the area lamp 250, the lamp fixture 300 may include thermal radiation fins 272, which act as a heat sink for helping to dissipate heat from the LED chip 108. The lamp fixture may further comprise a lamp hood 304 as a means of directing the distribution of light from the LED module 100. In a preferred embodiment, the lamp fixture 300 may be about 381 millimeters tall, while the external diameter of the lamp hood 304 may be about 432 millimeters.

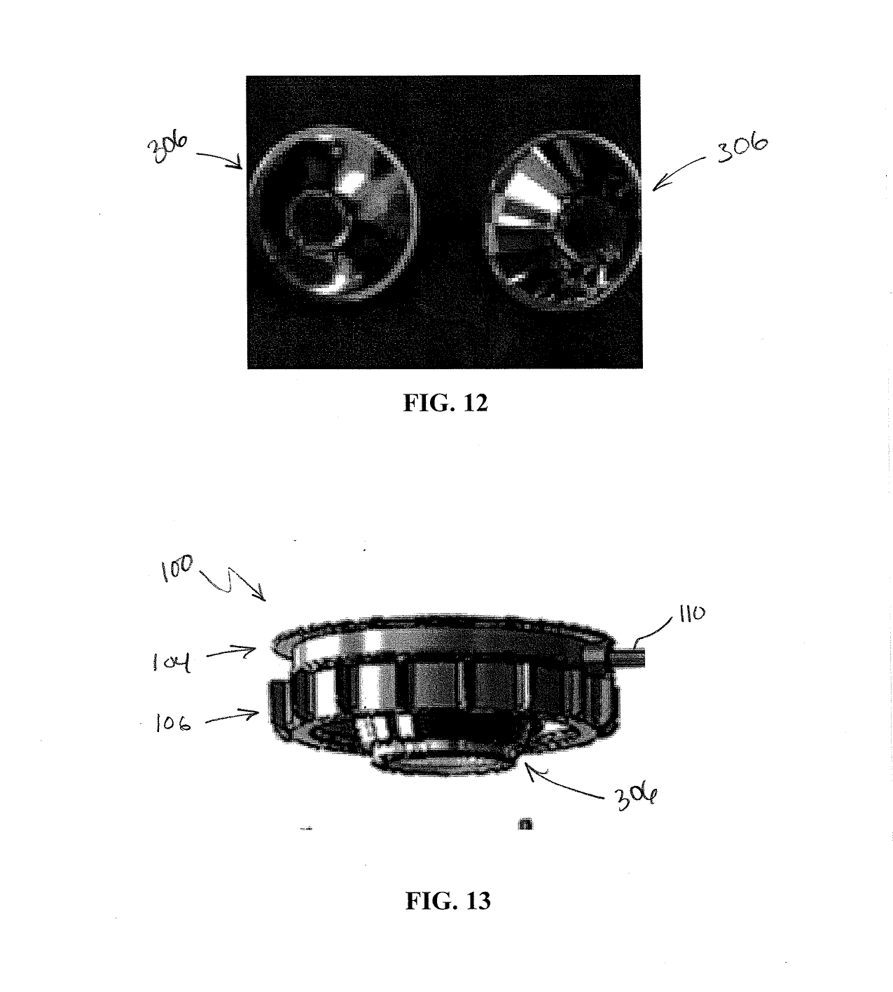

Now referring to FIG. 12, the lamp fixture 300 may utilize a highly-reflective optical module 306 in some embodiments. The highly-reflective optical module 306 may be tapered to help focus the light from the LED chip 108 into a pointed distribution.

FIG. 13 shows how the LED module 100 may receive the optical module 306. The optical module 306 may be secured to the LED module 100 in a number of ways including, for example and without limitation, a separate set of threads, “J” shaped slots that mate with the twist-lock studs 148 within the platform 102, or a weather-proof gasket. The present disclosure contemplates that in some embodiments the optical module 306 will be replaceable while in other embodiments the optical module 306 will be reusable after being disassembled from the replaceable unit 114.

It will be understood that the embodiments of the present invention which have been described are illustrative of some of the applications of the principles of the present invention. Numerous modifications may be made by those skilled in the art without departing from the true spirit and scope of the invention

1. A high-powered LED module containing an LED chip, said LED module configured to be quickly replaced in the field when the useable life of said LED chip expires, comprising:
a platform having an open end and a closed end, wherein the closed end includes a bottom surface and a top surface;
said LED chip affixed to the bottom surface of the closed end of the platform, the LED chip having a light-emitting surface that is capable of emitting light, wherein the light-emitting surface of the chip faces the open end of the platform;
a first collar having a first set of threads, the first collar sized such that the platform can be positioned generally within the first collar; and
a second collar having second set of threads that can engage the first set of threads of the first collar, wherein the platform with the affixed LED chip may be secured within the first collar by threading the second set of threads of the second collar onto the first set of threads of the first collar and said affixed LED chip can be replaced without the need for tools when the useable life of said LED chip expires.

2. The LED module of claim 1, wherein the platform, the first collar, and the second collar are generally cylindrical.

3. The LED module of claim 1, wherein the LED module is capable of generating over 6,000 lumens of light.

4. The LED module of claim 1, wherein said first collar further comprises a rim, said rim used for attaching the LED module to another object.

5. The LED module of claim 4 wherein said another object includes one or more of a canopy, a wall pack, a high bay fixture, a parking lot fixture or a decorative pendant light.

6. The LED module of claim 1, wherein said platform is made from aluminum.

7. The LED module of claim 1, wherein said platform is made from steel.

8. A method for replacing an LED chip in a high-powered LED module without tools after said LED chip has reached the end of its useful life, the method comprising the steps of:
removing from a first collar, having a first set of threads, a second collar of a platform, having a second set of threads, said platform having an open end and a closed end, wherein the closed end includes a bottom surface and a top surface, wherein said LED chip is affixed to the bottom surface of the closed end of the platform;
replacing said platform with a replacement platform, said replacement platform having a third collar, a second open end and a second closed end, wherein the second closed end includes a second bottom surface and a second top surface, wherein a replacement LED chip is affixed to the second bottom surface of the second closed end of the replacement platform, wherein the replacement platform with the affixed replacement LED chip may be secured within the first collar by threading the third set of threads of the third collar onto the first set of threads of the first collar, such that said affixed replacement LED chip can be replaced without the need for tools.

9. The method of claim 8 for replacing an LED chip in a high-powered LED module without tools after said LED chip has reached the end of its useful life, wherein said removing from a first collar includes unscrewing the second collar from the first collar.

10. The method of claim 8 for replacing an LED chip in a high-powered LED module without tools after said LED chip has reached the end of its useful life, wherein said replacing said platform with a replacement platform includes screwing the third collar onto the first collar.

11. The method of claim 8 for replacing an LED chip in a high-powered LED module without tools after said LED chip has reached the end of its useful life, wherein said replacement LED chip contains a light-emitting surface that is capable of emitting light, wherein the light-emitting surface of the LED chip faces the open end of the second platform.

12. A method for replacing an LED chip in a high-powered LED module without tools after said LED chip has reached the end of its useful life, the method comprising the steps of:
removing from a first collar, having a first set of threads, a second collar of a platform, having a second set of threads, said platform having an open end and a closed end, wherein the closed end includes a bottom surface and a top surface, wherein said LED chip is affixed to the bottom surface of the closed end of the platform;
eliminating said LED chip from said bottom surface of the closed end of the platform;
attaching a replacement LED chip to said bottom surface of the closed end of the platform;
replacing said platform having said second collar, into said first collar, wherein said platform with the replacement LED chip may be secured within the first collar by threading the second set of threads of the second collar onto the first set of threads of the first collar, such that said affixed replacement LED chip can be replaced without the need for tools.

13. The method of claim 12 for replacing an LED chip in a high-powered LED module without tools after said LED chip has reached the end of its useful life, wherein said removing from a first collar includes unscrewing the second collar from the first collar.

14. The method of claim 12 for replacing an LED chip in a high-powered LED module without tools after said LED chip has reached the end of its useful life, wherein said eliminating said LED chip means disconnecting a cord and a power plug from a source of electricity.

15. The method of claim 12 for replacing an LED chip in a high-powered LED module without tools after said LED chip has reached the end of its useful life, wherein said attaching a replacement LED chip means connecting a replacement cord and a replacement power plug to a source of electricity.

16. The method of claim 12 for replacing an LED chip in a high-powered LED module without tools after said LED chip has reached the end of its useful life, wherein said replacing said platform includes screwing the second collar onto the first collar.

17. The method of claim 12 for replacing an LED chip in a high-powered LED module without tools after said LED chip has reached the end of its useful life, wherein said replacement LED chip contains a light-emitting surface that is capable of emitting light, wherein the light-emitting surface of the replacement LED chip faces the open end of the second platform.
